(19) United States
(12) Patent Application Publication
(10) Pub. No.: US 2017/0059856 A1
(43) Pub. Date: Mar. 2, 2017

(54) LIGHT SOURCE DRIVING APPARATUS AND IMAGE DISPLAY APPARATUS

(71) Applicant: JVC KENWOOD CORPORATION, Yokohama-shi (JP)

(72) Inventor: Yoshiaki WAGATSUMA, Yokohama-shi (JP)

(21) Appl. No.: 15/348,497

(22) Filed: Nov. 10, 2016

Related U.S. Application Data
(63) Continuation of application No. PCT/JP2015/066050, filed on Jun. 3, 2015.

(30) Foreign Application Priority Data
Jun. 18, 2014 (JP) 2014-125312

(51) Int. Cl. G02B 26/10; G09G 3/02; H01S 5/00; H01S 5/0683; H01S 5/40

(52) U.S. Cl. CPC G02B 26/101; H01S 5/0683; H01S 5/4012; H01S 5/4093; H01S 5/0071; G09G 3/02; G09G 2330/021; G09G 2320/064

(57) ABSTRACT

A light source emits a laser light. A driver drives the light source based on a driving signal constituted by a pulse that changes a driving current value. When a luminance corresponding to a first laser output power that exceeds a threshold value is to be expressed, a controller controls the driver to supply to the light source a pulse having a first duty cycle at a first driving current value corresponding to the first laser output power. When a luminance corresponding to a second laser output power that is equal to or less than the threshold value is to be expressed, the controller controls the driver to supply to the light source a pulse having a second duty cycle that is smaller than the first duty cycle at a second driving current value corresponding to a third laser output power that exceeds the threshold value.

### CROSS REFERENCE TO RELATED APPLICATION

This application is a Continuation of PCT Application No. PCT/JP2015/066050, filed on Jun. 3, 2015, and claims the priority of Japanese Patent Application No. 2014-125312, filed on Jun. 18, 2014, the entire contents of both of which are incorporated herein by reference.

### BACKGROUND

The present disclosure relates to a light source driving apparatus that drives a semiconductor laser, and an image display apparatus equipped with a light deflector.

Light deflectors in which MEMS (Micro Electro Mechanical System) technology is used have been developed in recent years. A light deflector is used as a display device for displaying an image. A laser light emitted from a semiconductor laser is caused to fall on a mirror of the light deflector. The mirror deflects the laser light two-dimensionally. With this action, the light deflector scans the laser light horizontally and vertically, thereby displaying an image on a screen.

As disclosed in Japanese Unexamined Patent Application Publication No. 2013-130832, the light deflector is used in a head-up display in a vehicle, for example. The head-up display is an example of an image display apparatus.

### SUMMARY

The relationship between a driving current value that drives a semiconductor laser and a laser output power of a laser light emitted from the semiconductor laser is called an I-L characteristic. When the driving current value reaches up to or exceeds a predetermined threshold value, the semiconductor laser emits a laser light. As per the I-L characteristic, an increase in the driving current value results in an almost linear increase in laser output power.

For example, during nighttime, it may be necessary to lower the luminance of an image displayed by the image display apparatus. To display a low-luminance image, the laser output power needs to be reduced by reducing the driving current value.

In the region near the threshold value having a small driving current value, however, a kink region where the laser output power does not increase linearly is present.

Consequently, if the driving current value is reduced to reduce the laser output power, a laser light at a laser output power based on a driving current value within the kink region is emitted.

I-L characteristic is different for each of the semiconductor lasers emitting a red (R) light, a green (G) light, or a blue (B) light. Therefore, if the laser lights, namely the R, G, and B lights, are generated at a laser output power based on the driving current value within the kink region, the resultant color will be different than the color originally sought to be obtained.

An aspect of the embodiments provides a light source driving apparatus including: a light source constituted by a semiconductor laser that emits a laser light; a driver configured to drive the light source based on a driving signal constituted by a pulse having a predetermined duty cycle that changes a driving current value; and a controller configured to control the driver.

The controller, when a luminance corresponding to a first laser output power exceeding a threshold value, which is a predetermined laser output power, is to be expressed by the laser light that is output by the light source, is configured to control the driver to supply to the light source a driving signal constituted by a pulse having a first duty cycle at a first driving current value corresponding to the first laser output power such that the light source emits a laser light having the first laser output power.

The controller is configured, when a luminance corresponding to a second laser output power that is equal to or less than the threshold value is to be expressed by the laser light that is output by the light source, to control the driver to supply to the light source a driving signal constituted by a pulse having a second duty cycle that is smaller than the first duty cycle at a second driving current value corresponding to a third laser output power such that the light source emits a laser light having the third laser output power that exceeds the threshold value instead of the second laser output power.

The controller is configured to set a laser output power that is greater than a maximum laser output power within a kink region of an I-L characteristic possessed by the semiconductor laser as the threshold value.

### BRIEF DESCRIPTION OF THE DRAWINGS

FIG. 1 is a block diagram of a light source driving apparatus and an image display apparatus according to at least one embodiment.

FIG. 2 is a perspective view of a schematic configuration of an image display apparatus equipped with a laser light source and a light deflector.

FIG. 3 is a diagram showing an example of an I-L characteristic of a semiconductor laser.

FIG. 4 is a diagram showing a comparison between a driving method of a normal semiconductor laser and a driving method of a semiconductor laser included in the image display apparatus according to the embodiment.

FIG. 5 is a diagram explaining an operation of displaying an image by implementing the driving method of the semiconductor laser on the light source driving apparatus according to the embodiment.

### DETAILED DESCRIPTION

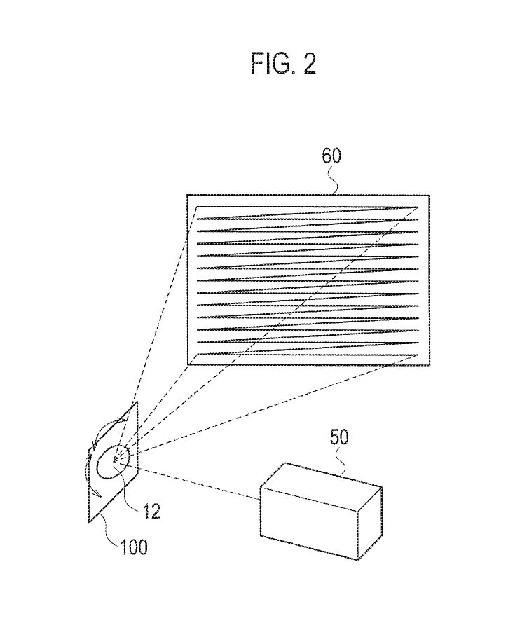

A light source driving apparatus and an image display apparatus according to the embodiment are explained below, while referring to the accompanying drawings. As shown in FIG. 2, the image display apparatus according to the embodiment schematically includes a laser light emitter 50 that emits a laser light, and a light deflector 100 that deflects the laser light horizontally and vertically to display an image on a screen 60.

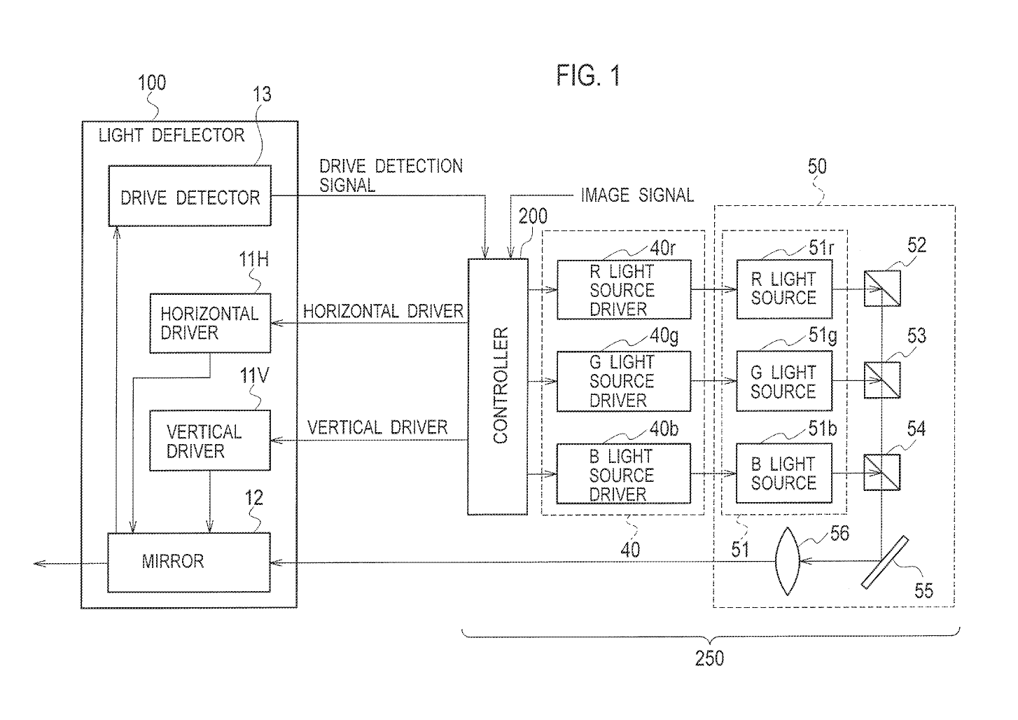

A detailed configuration and operation of the light source driving apparatus and the image display apparatus according to the embodiment are explained below, while referring to FIG. 1. The light deflector 100, shown in FIG. 1, has an integrated configuration including a horizontal deflection element (not shown) that deflects the laser light horizontally, and a vertical deflection element (not shown) that deflects the laser light vertically.

The light deflector 100 includes a mirror 12, a horizontal driver 11H, a vertical driver 11V, and a drive detector 13. The horizontal driver 11H is a driving mechanism that drives the mirror 12 horizontally, and the vertical driver 11V is a driving mechanism that drives the mirror 12 vertically. The drive detector 13 can include a detecting circuit equipped with a Hall Effect element or a piezoelectric element, for example.

An image signal corresponding to an image to be displayed by the image display apparatus is input into a controller 200. The controller 200 generates, based on a horizontal synchronizing signal of the input image signal, a horizontal driving signal to swing the light deflector 100 in a horizontal direction, and supplies the generated horizontal driving signal to the horizontal driver 11H.

The controller 200 generates, based on a vertical synchronizing signal of the input image signal, a vertical driving signal to swing the light deflector 100 in a vertical direction, and supplies the generated vertical driving signal to the vertical driver 11V. A drive detection signal generated from the detection of swinging of the horizontal deflection element by the drive detector 13 is input into the controller 200. The controller 200 can include a microprocessor or FPGA (Field Programmable Gate Array) and the like, for example.

A driver 40 includes an R light source driver 40r, a G light source driver 40g, and a B light source driver 40b. The R light source driver 40r, the G light source driver 40g, and the B light source driver 40b drive the laser light emitter 50 under the control of the controller 200. The R light source driver 40r, the G light source driver 40g, and the B light source driver 40b can each include, for example, a constant-current type driving circuit.

The laser light emitter 50 includes a light source 51, prisms 52 to 54, a mirror 55, and a lens 56. The light source 51 includes an R light source 51r that emits an R laser light, a G light source 51g that emits a G laser light, and a B light source 51b that emits a B laser light. The R light source 51r, the G light source 51g, and the B light source 51b are respectively constituted by a semiconductor laser.

The R light source driver 40r drives the R light source 51r, the G light source driver 40g drives the G light source 51g, and the B light source driver 40b drives the B light source 51b. The driver 40 supplies to the light source 51, excluding when displaying a low-luminance image as explained later, a driving signal that has a constant pulse width and whose driving current value changes (increases or decreases) according to the image luminance value (respective pixel value) to drive each of the R light source 51r, the G light source 51g, and the B light source 51b.

The controller 200 controls the driver 40 to supply to the light source 51 a driving signal that has a driving current value according to the respective pixel values.

The prism 52 bends an optical path of the R laser light emitted from the R light source 51r by 90 degrees. The prism 53 synthesizes the R laser light and the G laser light. The prism 54 synthesizes the synthesized light of the R laser light, the G laser light, and the B laser light.

The controller 200 controls the driver 40 to output the synthesized light through the prism 54 corresponding to the input image signal. The mirror 55 reflects a synthesized light of the R, G, and B laser lights that is output by the prism 54. The lens 56 collects the synthesized light from the mirror 55, and projects the same on the mirror 12.

The driver 40, the laser light emitter 50, and the controller 200, shown in FIG. 1, constitute a light source driving apparatus 250 of the embodiment.

The mirror 12 is swung to scan the laser light in a horizontal direction of the screen 60 with the horizontal deflection element. The mirror 12 is swung to scan the laser light in a vertical direction of the screen 60 with the vertical deflection element.

Because of the horizontal and vertical scanning of the laser light by the light deflector 100, an image based on the image signal is displayed on the screen 60.

The light deflector 100 and the light source driving apparatus 250, shown in FIG. 1, constitute the image display apparatus of the embodiment.

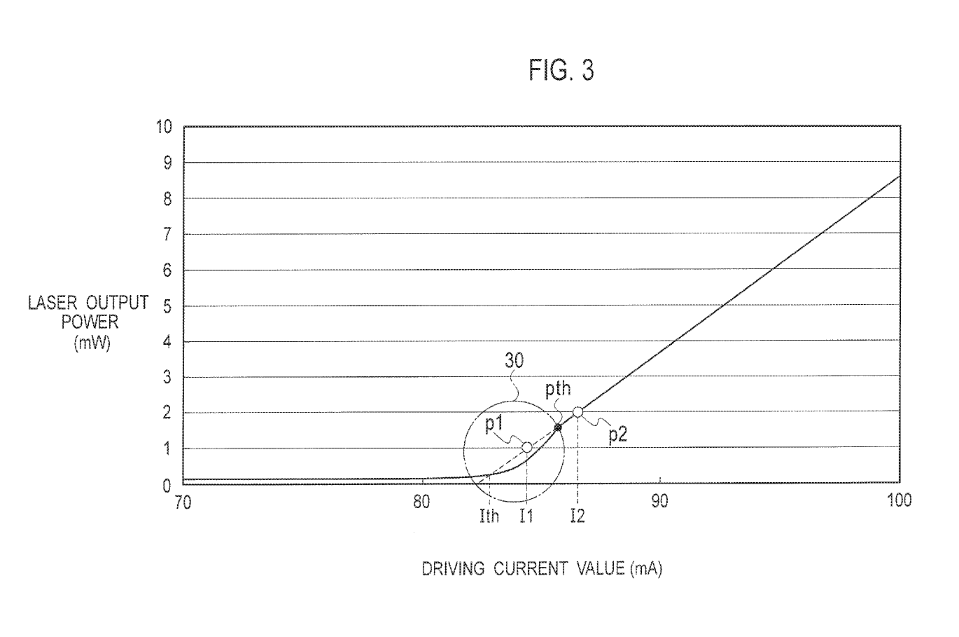

FIG. 3 illustrates an I-L characteristic of any of the semiconductor lasers among the R light source 51r, the G light source 51g, and the B light source 51b. As shown in FIG. 3, when the driving current value reaches up to or exceeds a threshold value Ith, the semiconductor laser starts emitting a laser light. The overall relationship between the driving current value and the laser output power is almost linear.

In FIG. 3, the point p1 is a point where the laser output power is 1 mW, and the point p2 is a point where the laser output power is 2 mW.

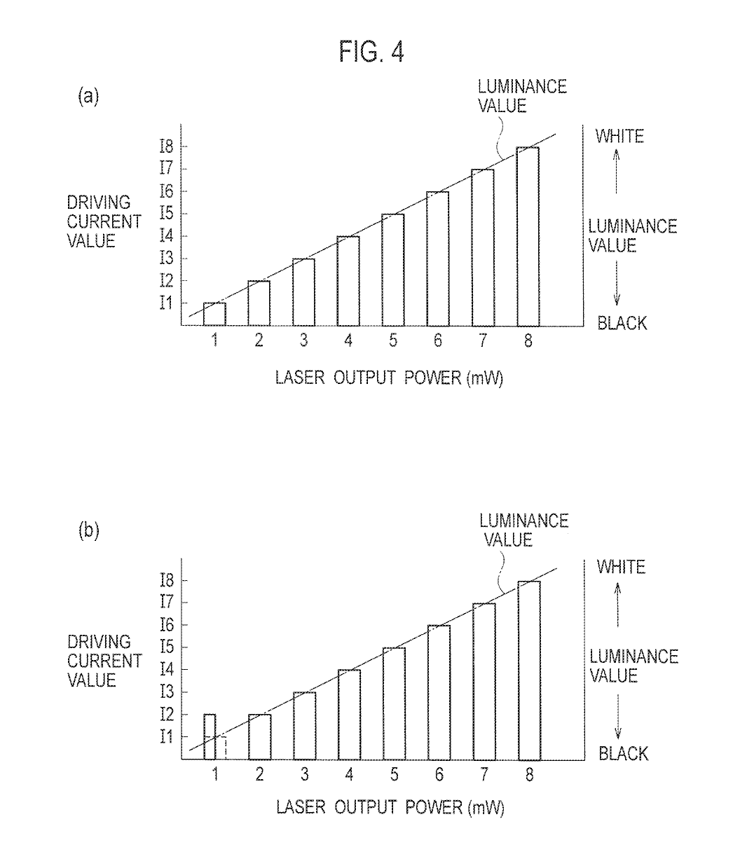

Assume that the I-L characteristic is overall a linear characteristic. As shown in (a) of FIG. 4, the laser output power needs to be increased as the luminance value of an image signal denoted by a dashed line increases. To simplify the explanation, the laser output power is shown only discretely as 1, 2, 3, 4, 5, 6, 7, and 8 (mW).

The driving current values to obtain the laser output powers of 1, 2, 3, 4, 5, 6, 7, and 8 (mW) are shown as I1, I2, I3, I4, I5, I6, I7, and I8. According to FIG. 3, for example, the driving current value I1 is about 85 (mA), and the driving current value I2 is about 87 (mA).

As shown in FIG. 3, a kink region 30 that is enclosed within a dashed line is present in a region near the threshold value Ith having a small driving current value. In the kink region 30, the driving current value and the laser output power do not have a linear relationship. Because the I-L characteristics of the R light source 51r, the G light source 51g, and the B light source 51b are not the same, the characteristic of the kink region 30 varies.

A dotted line shown inside the kink region 30, shown in FIG. 3, denotes the desired linear characteristic between the driving current value and the laser output power.

In FIG. 3, assume that the laser output power required to display a low-luminance image (pixel) is, for example, 1 mW. If the characteristic within the kink region 30 is linear as denoted by the dotted line, and the characteristic within the kink region 30 is the same, with respect to the I-L characteristic of each of the R light source 51r, the G light source 51g, and the B light source 51b, there will be almost no color variation.

In reality, however, the characteristic within the kink region 30 is not linear, and varies for the R light source 51r, the G light source 51g, and the B light source 51b. Consequently, color variation occurs.

To address this issue, in the embodiment, the driver 40 drives the light source 51 in the manner which is explained below. The driver 40, when the laser output power for displaying a predetermined low-luminance image is the laser output power within the kink region 30, drives the light source 51 at a greater driving current value that is outside the kink region 30, instead of the driving current value that is within the kink region 30.

In such a case, because the laser output power increases by the increase of the driving current value, the driver 40 decreases the duty cycle of the pulse to prevent the luminance value level from exceeding the predetermined low luminance level to be displayed.

For example, a case is explained here in which the laser output power required to display an image having the predetermined low luminance is 1 mW that is present within the kink region 30. As shown in FIG. 3, the driver 40, instead of the driving current value I1 that generates the laser output power of 1 mW, uses the driving current value I2 that is greater than the driving current value I1, and generates the laser output power 2 mW, for example, at the point p2 outside the kink region 30.

As shown in (b) of FIG. 4, the driver 40, to prevent the increase in the luminance expressed by the laser light by the increase in the laser output power by two times, uses a pulse width ½ of the normal pulse width used for driving the light source 51 at a driving current value that is outside the kink region 30.

The driver 40, if a 50% duty cycle is used for the normal pulse, drives the light source 51 at a pulse having a 25% duty cycle.

The luminance expressed by the laser light, when the driving signal constituted by a pulse having a 25% duty cycle at the driving current value I2 (laser output power: 2 mW) is supplied to the light source 51, is considered as a first luminance. A luminance expressed by the laser light, when the driving signal constituted by a pulse having a 50% duty cycle at the driving current value I1 (laser output power: 1 mW) is supplied to the light source 51, is considered as a second luminance. The first luminance and the second luminance are almost the same.

Therefore, according to the embodiment, the luminance does not increase even when the driver 40 increases the laser output power, and the image can be displayed at a desired luminance to be expressed by the laser light.

According to the embodiment, by using the laser output power that is outside the kink region 30 instead of using the laser output power that is within the kink region 30, the color variations can be minimized.

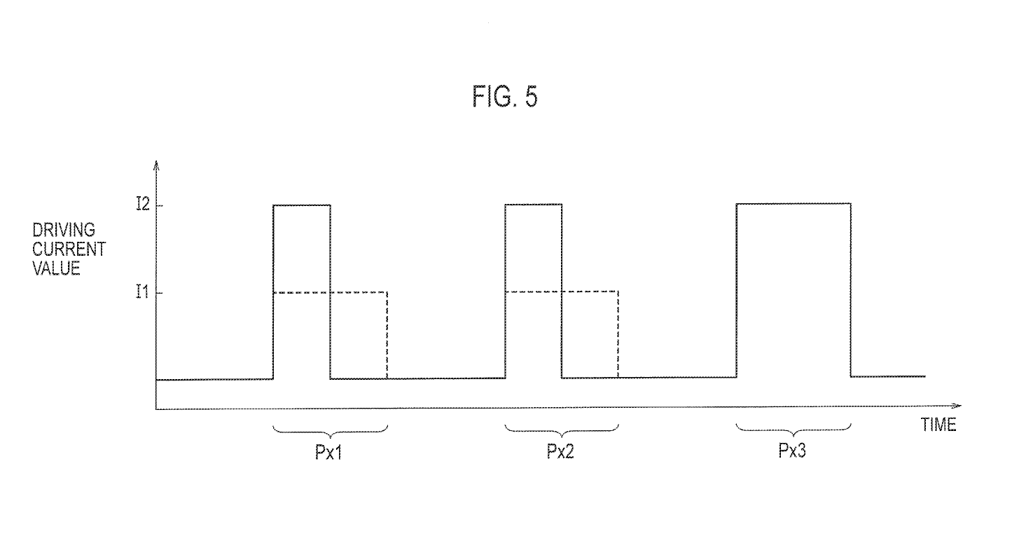

FIG. 5 illustrates an example in which pixels Px1 to Px3 among a plurality of pixels that constitute an image are to be displayed. To display the respective pixels by scanning the laser light horizontally and vertically with the light deflector 100, the light source driving apparatus 250 controls the luminance of the respective pixels according to the luminance value of a pixel signal constituting the image signal.

It is considered that originally, the pixels Px1 and Px2 are low-luminance pixels expressed by the laser output power of 1 mW by supplying the driving current value I1 to the light source 51. Moreover, it is considered that the pixel Px3 is a pixel of a luminance expressed by the laser output power of 2 mW by supplying the driving current value I2 to the light source 51.

As shown in FIG. 5, the driver 40, when displaying the pixels Px1 and Px2, drives the light source 51 with the driving signal constituted by a pulse having a 25% duty cycle at the driving current value I2, instead of the driving signal constituted by a pulse having a 50% duty cycle at the driving current value I1 denoted by the dotted line.

The driver 40, when displaying the pixel Px3, drives as per the normal method, the light source 51 with the driving signal constituted by the pulse having a 50% duty cycle at the driving current value I2.

In the above explanation, the luminance expressed by the laser output power at the point p1 that is within the kink region 30 is given as an example of a low-luminance pixel. The same is applicable when a luminance is expressed by a laser output power of a point other than the point p1 that is within the kink region 30.

The controller 200 can control the driver 40 in the manner as explained below. A point pth as shown in FIG. 3 is considered as a threshold value, indicating a predetermined laser output power.

The controller 200, when a luminance corresponding to a first laser output power that exceeds the threshold value pth is to be expressed by the laser light that is output by the light source 51, controls the driver 40 in the manner which is explained below.

The controller 200 controls the driver 40 to supply to the light source 51 a driving signal constituted by a pulse having a first duty cycle at a first driving current value corresponding to the first laser output power, such that the light source 51 emits the laser light having the first laser output power.

The first laser output power mentioned above is the desired laser output power that is greater than the threshold value pth. The first duty cycle is 50%, for example.

The controller 200, when a luminance corresponding to a second laser output power that is equal to or less than the threshold value pth is to be expressed by the laser light that is output by the light source 51, controls the driver 40 in the manner which is explained below.

The controller 200 controls the driver 40 to supply to the light source 51 a driving signal constituted by a pulse having a second duty cycle at a second driving current value corresponding to a third laser output power, such that the light source 51 emits the laser light having the third laser output power. The third laser output power mentioned above is the desired laser output power that exceeds the threshold value pth.

The controller 200 controls the driver 40 in the manner explained above such that the light source 51 emits the third laser output power instead of the second laser output power. The second duty cycle is smaller than the first duty cycle.

It is desirable that the controller 200 multiplies the second laser output power n times, and uses that value as the third laser output power. Moreover, it is desirable that the controller 200 multiplies the first duty cycle 1/n times, and uses that value as the second duty cycle. Here, ‘n’ is a number greater than 1 and desirably an integer, but it can also be a non-integer.

It is desirable that the controller 200 sets, as the threshold value pth, a laser output power that is equal to or greater than the maximum laser output power within the kink region 30 of the I-L characteristic possessed by the semiconductor laser.

The light source driving apparatus 250 can be used in devices other than the image display apparatus. When the light source driving apparatus 250 is to be used in an image display apparatus that displays an image by using a laser light emitted by the light source 51, the controller 200 can control the driver 40 in the manner as explained below.

The controller 200 controls the driver 40 such that the driver 40 increases the driving current value of the driving signal supplied to the light source 51 in proportion to the increase in the luminance value of the image signal for displaying an image.

With the method explained above, according to the embodiment the image display apparatus equipped with the light deflector 100 that displays the image by deflecting the laser light generated by the light source 51 horizontally and vertically and the light source driving apparatus 250, can minimize the color variations even when a low-luminance image is to be displayed.

The present invention is not limited to the embodiment explained above, and can be modified in a variety of ways without departing from the scope of the present invention. It is desirable, but not limited that the light deflector 100 is configured by using MEMS technology. It is desirable that the light deflector 100 has a functionality to deflect a laser light horizontally and vertically, and the actual configuration to achieve this functionality is not limited.

What is claimed is:

1. A light source driving apparatus comprising:
a light source constituted by a semiconductor laser that emits a laser light;
a driver configured to drive the light source based on a driving signal constituted by a pulse having a predetermined duty cycle that changes a driving current value; and
a controller configured to control the driver,
wherein the controller,
when a luminance corresponding to a first laser output power exceeding a threshold value, which is a predetermined laser output power, is to be expressed by the laser light that is output by the light source, is configured to control the driver to supply to the light source a driving signal constituted by a pulse having a first duty cycle at a first driving current value corresponding to the first laser output power such that the light source emits a laser light having the first laser output power,
when a luminance corresponding to a second laser output power that is equal to or less than the threshold value is to be expressed by the laser light that is output by the light source, is configured to control the driver to supply to the light source a driving signal constituted by a pulse having a second duty cycle that is smaller than the first duty cycle at a second driving current value corresponding to a third laser output power such that the light source emits a laser light having the third laser output power that exceeds the threshold value instead of the second laser output power, and
is configured to set a laser output power that is greater than a maximum laser output power within a kink region of an I-L characteristic possessed by the semiconductor laser as the threshold value.

2. The light source driving apparatus according to claim 1, wherein the controller
multiplies the second laser output power n times, where n is a number greater than 1, and uses that value as the third laser output power, and
multiplies the first duty cycle 1/n times and uses that value as the second duty cycle.

3. An image display apparatus comprising:
the light source driving apparatus according to claim 1; and
a light deflector configured to display an image by deflecting the laser light emitted by the light source horizontally and vertically.
